(19) United States
(12) Patent Application Publication
(10) Pub. No.: US 2009/0134786 A1
(43) Pub. Date: May 28, 2009

(54) Organic EL display device and manufacturing method thereof

(75) Inventors: Eiji Matsuzaki, Yokohama (JP); Yoshinori Ishii, Chiba (JP); Satoru Kase, Mobara (JP)

Correspondence Address: Stanley P. Fisher;Reed Smith LLP, Suite 1400, 3110 Fairview Park Drive, Falls Church, VA, 22042-4503, US

(73) Assignee: Hitachi Displays, Ltd.

(21) Appl. No.: 12/289,885

(22) Filed: Nov. 6, 2008

(30) Foreign Application Priority Data
Nov. 6, 2007 (JP) 2007-288959

(51) Int. Cl. H01L 51/52; H01L 51/56

(52) U.S. Cl. 313/504; 438/26

(57) ABSTRACT

A manufacturing method of an organic EL display device which can suppress a manufacturing cost while effectively preventing organic EL layers from being influenced by moisture is provided. An organic EL element is covered with a resin sheet. The resin sheet is adhered to a sealing substrate and an element substrate on which organic EL elements are formed by lamination. Laser beams are radiated to a terminal portion formed on the element substrate so as to generate impact waves in the terminal portion by laser beams thus removing the resin sheet from the terminal portion. Thereafter, edge portions of the sealing substrate and edge portions of the resin sheet are removed along a line a. Due to such steps, it is possible to manufacture highly reliable organic EL display devices at a low cost.

### CROSS-REFERENCE TO RELATED APPLICATION

The present application claims priority from Japanese application JP2007-288959 filed on Nov. 6, 2007, the content of which is hereby incorporated by reference into this application.

### BACKGROUND OF THE INVENTION

1. Field of the Invention

The present invention relates to an organic EL display device, and more particularly to a highly reliable top-emission-type organic EL display device which suppresses the generation of dark spots attributed to moisture.

2. Background Art

In an organic EL display device, an organic EL layer is sandwiched between a pixel electrode (lower electrode) and an upper electrode, a fixed voltage is applied to the upper electrode, and emission of light from the organic EL layer is controlled by applying a data signal voltage to the lower electrode thus forming an image. The data signal voltage is supplied to the lower electrode via a thin film transistor (TFT).

An organic EL display device is classified into a bottom-emission-type organic EL display device in which light emitted from organic EL layers is taken out in the direction of a glass substrate on which the organic EL layers and the like are formed and a top-emission-type organic EL display device in which light emitted from organic EL layers is taken out in the direction opposite to a glass substrate on which the organic EL layers and the like are formed. The top-emission-type organic EL display device has an advantage that the respective organic EL layers can ensure a large light emission area thus increasing the brightness of a display.

When moisture is present in an organic EL material used in an organic EL display device, the light emission characteristic is deteriorated and hence, when the organic EL display device is operated for a long time, portions of the organic EL material which are deteriorated with moisture do not emit light. These portions appear as dark spots on a display region. The dark spots grow with time and become a defect of an image.

To prevent the generation or the growth of the dark spots, it is necessary to prevent the intrusion of moisture in the organic EL display device or to remove the intruded moisture from the organic EL display device. Accordingly, an element substrate on which an organic EL layer is formed is sealed by a sealing substrate thus preventing the intrusion of moisture into the inside of the organic EL display device from the outside. On the other hand, to remove moisture intruded into the inside of the organic EL display device, a desiccant is arranged in the inside of the organic EL display device. This organic EL display device is referred to as a hollow-sealed-type organic EL display device.

The hollow-sealed-type organic EL display device has drawbacks such as difficulty in adjusting a gap between the element substrate and the sealing substrate, difficulty in adjusting pressure in the sealed inside, contamination of the organic EL material by a gas discharged from a sealing agent at the time of performing the sealing operation using a sealing agent or a low throughput.

To cope with such drawbacks attributed to the hollow sealed structure, there has been known a technique which sandwiches a resin sheet having a fixed film thickness between an element substrate and a sealing substrate thus protecting an organic EL material from moisture using such a resin sheet. This technique is referred to as solid sealing.

JP-2004-139977 (patent document 1) discloses an example of solid sealing, and FIG. 8A to FIG. 8D show the constitution of such an example described in patent document 1. In FIG. 8A to FIG. 8D, a photo curing resin 102 which is formed on a light transmitting film 101 is laminated to an element substrate 10 on which organic EL layers 22 are formed using a compression bonding roller 105 which is heated at a temperature of 80° C. Next, ultraviolet rays are radiated to the photo curing resin 102 so as to cure the photo curing resin 102 and, thereafter, the light transmitting film 101 is peeled off thus acquiring an organic EL display device sealed with the photo curing resin. Further, when necessary, the organic EL elements are covered with a silicon nitride film.

An article written by Shinya Saeki in Nikkei Electronics issued on Sep. 10, 2007, No. 960 pp 10-11 (non-patent document 1) discloses a following technique for sealing an organic EL display device as shown in FIG. 9A to FIG. 9E. That is, resin films 107 are laminated to portions of a sealing substrate 40 corresponding to organic EL elements 103 and, thereafter, a sealing agent 108 is drawn around the resin film 107. The sealing substrate 40 on which the resin films 107 are formed using the sealing agents 108 and an element substrate 10 on which the organic EL elements 103 are formed are laminated to each other. Next, ultraviolet rays are radiated from the sealing substrate 40 so as to perform heat treatment at a temperature which falls within a range from 80° C. to 100° C. Due to such heat treatment, the sealing agents 108 are cured and, at the same time, the resin film 107 which obtains fluidity spreads in a space formed by the sealing substrate 40, the element substrate 10 and the sealing agent 108 and is filled in the space. Finally, the sealed laminated structure is divided into individual organic EL display panels as products.

JP-2006-66364 (patent document 2) discloses the constitution in which a plurality of display elements are formed on a mother substrate, a sealing film is formed on the plurality of display elements collectively and, thereafter, a protective film is removed from terminal portions of the respective elements by laser ablation. FIG. 10A and FIG. 10B show the constitution described in patent document 2, wherein a plurality of display elements each having a light emitting portion 207 and terminal portions 209 are formed on the mother substrate 206, and the display elements are covered with the protective film 208. The protective film 208 is removed from portions 210 of the terminal portion 209 by laser ablation thus forming opening portions 210.

### SUMMARY OF THE INVENTION

With respect to the technique described in “patent document 1”, the constitution which protects the organic EL layers by laminating the resin sheet to the individual organic EL display devices is described. However, “patent document 1” neither describes nor suggests drawbacks or the like which may be caused due to covering of the individual organic EL display devices with the resin sheet when the plurality of organic EL panels are formed on the mother substrate and are separated from each other.

With respect to the technique described in “non-patent document 1”, it is necessary to take a balance in height between the resin film and the sealing material. This is because when the balance in height collapses, a life time of the organic EL display device is deteriorated. Further, although the resin film exhibits fluidity and spreads in the heating step after sealing, pressure inside the organic EL display device is increased due to such spread of the resin film and hence, a leak path leading to the outside is formed thus giving rise to possibility that a life time of the organic EL display device is deteriorated. To overcome this drawback, the lamination of a sealing glass on which a resin film is formed and an element substrate on which organic EL layers are formed in a vacuum may be considered. However, the resin film exhibits fluidity and spreads and hence, a gap between the sealing glass and the element substrate is changed, that is, becomes irregular. Such a case also forms a leak path leading to the outside thus giving rise to possibility that a life time of the organic EL display device is deteriorated. Further, due to the influence of a gas discharged when the sealing agent is cured exerted on the resin sheet, there exists possibility that sealing ability is lowered.

The technique described in “non-patent document 1” uses a patterned resin sheet and hence, it is necessary to form the resin sheet by patterning in advance. Accordingly, this technique requires, for performing such patterning, a cutting step, a dispensing step of a sealing agent to a resin sheet-applied sealing substrate, a laminating step necessary for accurate positioning and the like. Accordingly, this technique gives rise to a drawback that a yield rate of the sealing step is lowered.

The technique described in “patent document 2” performs forming of the opening portion for every individual terminal and hence, productivity is small. Accordingly, it is necessary to increase the number of facilities to increase a production quantity and the increase of the number of facilities pushes up a manufacturing cost. Further, laser beams having high energy is necessary for performing laser ablation and hence, there arises possibility that connection terminals are damaged.

The present invention has been made to overcome the above-mentioned drawbacks, and it is an object of the present invention to realize a solid-sealing-type organic EL display device which exhibits reliable sealing and a high throughput.

To overcome the above-mentioned drawbacks, according to the present invention, a sealing substrate to which one large-sized resin sheet is laminated is laminated to an element substrate on which a plurality of organic EL elements is formed by way of a resin sheet thus forming a mother organic EL display panel. Then, laser beams are radiated to regions such as terminal portions from which it is necessary to remove the resin sheet under special conditions. The radiation of laser beams generates impact waves in the element substrate so as to peel off the resin sheet from the element substrate. A step of peeling off the resin sheet using the impact waves generated by laser beams may be performed before the individual organic EL display devices are removed from the mother organic EL display panel or after such removal of the organic EL display devices. Followings are specific means to overcome the above-mentioned drawbacks.

(1) According to a first aspect of the present invention, there is provided an organic EL display device which includes: an element substrate which includes a display region on which pixels each of which has an upper electrode, a lower electrode, and an organic EL layer sandwiched between the upper electrode and the lower electrode are formed in a matrix array and a terminal portion which supplies an electric current and a signal to the display region; and a sealing substrate which seals the display region, wherein a resin sheet is sandwiched between the element substrate and the sealing substrate, and the resin sheet is removed from the terminal portion by impact peeling using laser beams.

(2) In the organic EL display device having the constitution (1), the resin sheet is laminated to the sealing substrate, and the resin sheet is also laminated to the element substrate.

(3) In the organic EL display device having the constitution (1), an edge portion of the resin sheet retracts more inwardly than an edge portion of the sealing substrate and an edge portion of the element substrate.

(4) In the organic EL display device having the constitution (1), an organic seal is formed on an edge portion of the resin sheet.

(5) In the organic EL display device having the constitution (1), a protective film is formed on the upper electrode.

(6) In the organic EL display device having the constitution (1), the protective film is an inorganic film and contains any one of SiNx, SiOx and SiNxOy.

(7) According to a second aspect of the present invention, there is provided a manufacturing method of an organic EL display device which includes an element substrate which includes a display region on which pixels each of which has an upper electrode, a lower electrode, and an organic EL layer sandwiched between the upper electrode and the lower electrode are formed in a matrix array and a terminal portion which supplies an electric current and a signal to the display region; a sealing substrate which seals the display region; and a resin sheet which is sandwiched between the element substrate and the sealing substrate, wherein the manufacturing method includes the steps of: manufacturing a mother element substrate on which a plurality of element regions each of which has the display region and the terminal portion are formed; laminating one resin sheet to a mother sealing substrate; laminating the mother element substrate and the mother sealing substrate to each other by way of the resin sheet thus manufacturing a mother organic EL display panel; separating the mother organic EL display panel into a plurality of individual organic EL display panels; and radiating laser beams to a terminal portion of the separated organic EL display panel thus peeling off the resin sheet from the terminal portion by impact waves generated by the laser beams.

(8) According to a third aspect of the present invention, there is provided a manufacturing method of an organic EL display device which includes an element substrate which includes a display region on which pixels each of which has an upper electrode, a lower electrode, and an organic EL layer sandwiched between the upper electrode and the lower electrode are formed in a matrix array and a terminal portion which supplies an electric current and a signal to the display region; a sealing substrate which seals the display region, and a resin sheet which is sandwiched between the element substrate and the sealing substrate, wherein the manufacturing method includes the steps of: manufacturing a mother element substrate on which a plurality of element regions each of which has the display region and the terminal portion are formed; laminating one resin sheet to the mother sealing substrate; laminating the mother element substrate and the mother sealing substrate to each other by way of the resin sheet thus manufacturing a mother organic EL display panel; radiating laser beams to the terminal portion of the element region thus peeling off the resin sheet from the terminal portion by impact waves generated by the laser beams; and separating the mother organic EL display panel for respective element regions.

To cope with drawbacks caused by the hollow sealed structure, the resin sheet having the fixed film thickness is sandwiched between the element substrate and the sealing substrate thus proving solid sealing which protects the organic EL material from moisture using the resin sheet. Due to such constitution, a manufacturing cost can be suppressed and, at the same time, the manufacture can be performed while maintaining reliability.

To the sealing mother substrate corresponding to the mother element substrate on which the plurality of organic EL elements are formed, one large-sized resin sheet for a sealing purpose is laminated. Accordingly, the resin sheet is not subject to forming before the lamination of the resin sheet to the sealing substrate and hence, the contamination of the resin sheet can be reduced. Accordingly, it is possible to provide the highly reliable sealing using the resin sheet.

Although it is necessary to remove the resin sheet from the terminal portion, by radiating laser beams to an interface portion between the terminal portion and the resin sheet under particular conditions, impact waves are generated on the element substrate by laser beams thus removing the resin sheet. Since this removal method is different from a method which evaporates the resin sheet by heating using laser beams and hence, there is no possibility that the terminal portion is damaged.

According to the present invention, the highly reliable solid sealing which protects the organic EL element from moisture can be performed with a high throughput. That is, the present invention can realize the highly reliable organic EL display device which can also suppresses a manufacturing cost.

### BRIEF DESCRIPTION OF THE DRAWINGS

FIG. 1 is a cross-sectional view of a display region of an organic EL display device;

FIGS. 2A1-2F are views showing manufacturing steps of organic EL display devices of an embodiment 1;

FIGS. 3A1-3F are views showing manufacturing steps of organic EL display devices of an embodiment 2;

FIGS. 4A1-4E are views showing manufacturing steps of organic EL display devices of an embodiment 3;

FIGS. 5A-5D are views showing manufacturing steps of organic EL display devices of an embodiment 4;

FIG. 6A to FIG. 6C are views showing an organic EL display device of an embodiment 5;

FIG. 7 is a cross-sectional view of an organic EL display device of an embodiment 6;

FIG. 8A to FIG. 8D are views showing a conventional example of an organic EL display device;

FIG. 9A to FIG. 9E are views showing another conventional example of an organic EL display device; and

FIG. 10A and FIG. 10B are views showing still another conventional example of an organic EL display device.

### DESCRIPTION OF THE PREFERRED EMBODIMENTS

The gist of the present invention is as follows. While protecting the organic EL layer 22 formed on the element substrate 10 from moisture using the resin film, it is necessary to remove the resin film from the terminal portion or the like. In the present invention, laser beams are used for removing the resin film from the terminal portion or the like. However, different from the related art in which a resin film is evaporated or sublimated with heat by the radiation of laser beams or an ablation phenomenon is used, according to the present invention, the resin film is peeled off from the terminal portion or the like using the impact waves generated on the substrate by the radiation of laser beams, and the peeled-off resin film is removed. Since the present invention adopts neither the method which evaporates resin with heat by laser beams nor the method which evaporates resin in an explosive manner by ablation, the present invention can peel off the resin sheet 30 at a low temperature which causes no damage to the terminal portion and at a high speed.

To generate the impact waves by radiation of laser beams, a pulse width, pulse intervals and the like of laser beams are important. As a typical example, the pulse width of laser beams is approximately 10 nsec, and the pulse intervals of laser beams are approximately 25 μsec. In this manner, the pulse intervals are extremely long compared to the pulse width and hence, heat is not accumulated in a portion to which laser beams are radiated. When laser beams having such pulses are radiated, the laser energy is converted into heat and, thereafter, heat is immediately converted into mechanical vibratory energy thus causing minute vibrations in the substrate thus generating the impact waves. The resin film is removed from the element substrate 10 or the like due to this mechanical energy.

In this case, as laser beams, pulse beams of second harmonics (wavelength: 532 nm) generated by a YAG laser are used. However, it is necessary to change laser beams depending on a material property (for example, an absorption factor of illuminated light) of the substrate in which the impact waves are generated.

The vibratory energy is required to possess sufficient intensity to peel off the resin film laminated to the element substrate 10 or the like. On the other hand, when the vibratory energy is excessively strong, there exists possibility that a conductive thin film or an insulation thin film formed on the element substrate 10 is also peeled off. Accordingly, it is necessary to set the energy of laser beams to energy which is sufficient to peel off the resin film but cannot peel off the conductive thin film or the insulation thin film formed on the element substrate 10. That is, it is necessary to radiate laser beams having energy which falls within a specific range.

Hereinafter, the present invention is explained in detail in conjunction with embodiments.

### EMBODIMENT 1

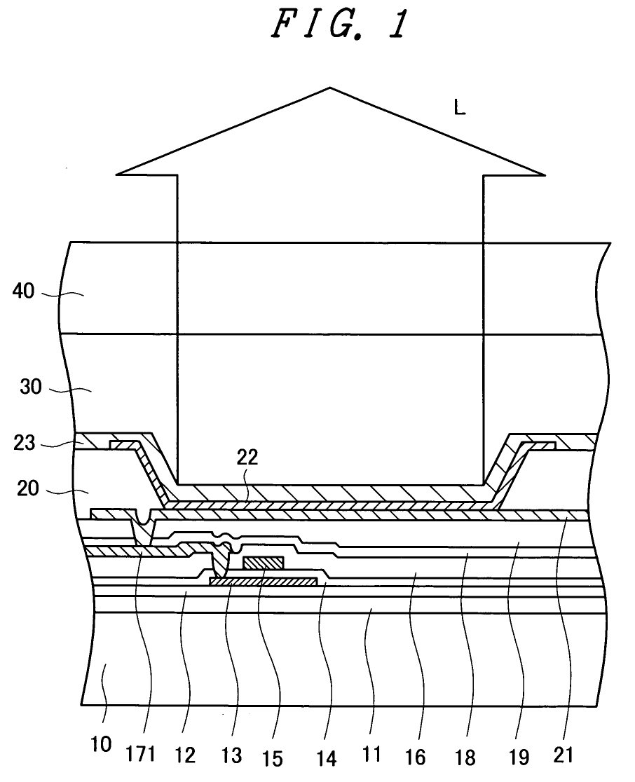

FIG. 1 is a cross-sectional view of a display region of a top-emission-type organic EL display device to which the present invention is applied. Although this embodiment is explained by taking the top-emission-type organic EL display device as an example, the present invention is also applicable to a bottom-emission type organic EL display device in the same manner. The top-emission-type organic EL display device can be classified into a top-anode-type organic EL display device in which an anode is arranged above an organic EL layer and a top-cathode-type organic EL display device in which a cathode is arranged above an organic EL layer. Although FIG. 1 shows the top-anode type organic EL display device, the present invention is also applicable to the top-cathode type organic EL display device in the same manner.

As shown in FIG. 1, a first background film 11 made of SiN and a second background film 12 made of SiO₂ are formed on an element substrate 10. These background films 11, 12 are provided for preventing impurities from a glass substrate from contaminating a semiconductor layer 13. The semiconductor layer 13 is formed on the second background film 12. In forming the semiconductor layer 13, an a-Si film is firstly formed by a CVD method and, thereafter, the a-Si film is formed into a poly-Si film by radiating laser beams to the a-Si film.

A gate insulation film 14 made of SiO₂ is formed so as to cover the semiconductor layer 13. A gate electrode 15 is formed in a state that the gate electrode 15 faces the semiconductor layer 13 in an opposed manner with the gate insulation film 14 sandwiched therebetween. Using the gate electrode 15 as a mask, the semiconductor layer 13 is doped with impurities such as phosphorus or boron by ion implantation so as to make the semiconductor layer 13 conductive thus forming a source portion or a drain portion in the semiconductor layer 13.

An interlayer insulation film 16 made of SiO₂ is formed so as to cover the gate electrode 15. The interlayer insulation film 16 is provided for ensuring the insulation between gate lines and drain lines 171. The drain line 171 is formed on the interlayer insulation film 16. The drain line 171 is connected with the drain of the semiconductor layer 13 via a through hole formed in the interlayer insulation film 16 and the gate insulation film 14.

Thereafter, to protect a thin film transistor (TFT) formed in the above-mentioned manner, an inorganic passivation film 18 made of SiN is formed on the interlayer insulation film 16 by coating. An organic passivation film 19 is formed on the inorganic passivation film 18. The organic passivation film 19 plays a role of protecting the TFT more completely together with the inorganic passivation film 18. The organic passivation film 19 also plays a role of leveling a surface on which an organic EL layer 22 is formed. Accordingly, the organic passivation film 19 has a large thickness of 1 to 4 μm.

A reflection electrode made of Al or Al alloy is formed on the organic passivation film 19. Since Al or Al alloy exhibits high reflectance, Al or Al alloy is preferably used as a material of the reflection electrode. The reflection electrode is connected with the drain line 171 via a through hole formed in the organic passivation film 19 and the inorganic passivation film 18.

This embodiment provides the top-anode-type organic EL display device and hence, a lower electrode 21 of the organic EL layer 22 constitutes a cathode. Accordingly, the Al layer or Al alloy layer which is used for forming the reflection electrode 24 is also used for forming the lower electrode 21 of the organic EL layer 22.

The organic EL layer 22 is formed on the lower electrode 21. The organic EL layer 22 is constituted of an electron transport layer, a light emission layer and a hole transport layer which are laminated from below. Here, an electron injection layer may be interposed between the electron transport layer and the lower electrode 21. Further, a hole injection layer may be interposed between the hole transport layer and an upper electrode 23. The upper electrode 23 which constitutes an anode is formed on the organic EL layer 22. In this embodiment, the upper electrode 23 is made of IZO. The IZO film is formed over the whole display region by vapor deposition. A thickness of the IZO film is set to approximately 30 nm for maintaining optical transmissivity. An ITO film may be used in place of the IZO film.

A material which can be used as an electron-transport-layer material is not specifically limited provided that the material exhibits electron transport property and can be easily formed into a charge-transfer complex by co-deposition with alkali metal and, for example, a metal complex such as tris(8-quinolinolato) aluminum, tris(4-methyl-8-quinolinolato) aluminum, bis (2-methyl-8-quinolinolato)-4-phenylphenolato-aluminum, bis [2-[2-hydroxyphenyl]benzooxazolato]zinc, 2-(4-biphenylyl)-5-(4-tert-butyphenyl)-1,3,4-oxadiazol, 1,3-bis[5-(p-tert-butylphenyl)-1,3,4-oxadiazol-2-yl]benzene or the like can be used.

A material which can be used as a light-emitting-layer material is not specifically limited provided that the material is made of a host material which has an electron-and-hole transporting ability, and a dopant which is added to the host material, emits a fluorescent light or a phosphorous light by re-coupling of the host material and forms a light emitting layer by co-vapor-deposition. For example, as the host material, a complex such as tris(8-quinolinolato) aluminum, bis (8-quinolinolato) magnesium, bis(benzo{f}-8-quinolinolato) zinc, bis(2-methyl-8-quinolinolato) aluminum oxide, tris (8-quinolinolato) indium, tris(5-methyl-8-quinolinolato) aluminum, 8-quinolinolato lithium, tris (5-chloro-8-quinolinolato) gallium, bis (5-chloro-8-quinolinolato) calcium, 5,7-dichloro-8-quinolinolato aluminum, tris (5,7-dibromo-8-hydroxyquinolinolato) aluminum, and poly (zinc(II)-bis(8-hydroxy-5-quinolinyl)methane), an anthracene derivative, a carbazole derivative, or the like can be used.

Further, the dopant is a material which captures electrons and holes in a host material and emits light by re-coupling. For example, the red dopant may be formed of a pyran derivative, the green dopant may be formed of a coumarin derivative, and the blue dopant may be formed of a substance which emits fluorescent light such as an anthracene derivative or a substance which emits phosphorescence such as an iridium complex and a pyridinato derivative.

The hole transport layer may be made of tetraaryl benzidine compound (triphenyl diamine: TPD), aromatic tertiary amine, hydrazone derivative, carbazole derivative, triazole derivative, imidazole derivative, oxadiazole derivative having an amino group, polythiophene derivative, copper phthalocyanine derivative or the like.

Here, to prevent the organic EL layer 22 from being broken at an edge portion thereof due to a broken step, a bank 20 is formed between the pixels. Further, the bank 20 prevents short-circuiting between the lower electrode 21 and the upper electrode 23. The bank 20 may be formed of an organic material, or the bank 20 may be formed of an inorganic material such as SiN. In forming the bank 20 using the organic material, in general, an acrylic resin or a polyimide resin is used.

An auxiliary electrode may be formed on the upper electrode 23 which is formed on the bank 20 for assisting the electrical conduction of the upper electrode 23. This is because when the resistance of the upper electrode 23 is large, brightness irregularities may occur. Although the auxiliary electrode is not used in this embodiment, it is needless to say that the present invention is also applicable to an organic EL display device which uses the auxiliary electrode.

In FIG. 1, a resin sheet 30 is formed on the upper electrode 23. The resin sheet 30 is adhered to the upper electrode 23 by a lamination method. A thickness of the resin sheet 30 is set to 10 μm, for example. The resin sheet 30 is made of an acrylic resin, for example. A sealing substrate 40 is formed on the resin sheet 30. The sealing substrate 40 and the resin sheet 30 are also adhered to each other by a lamination method.

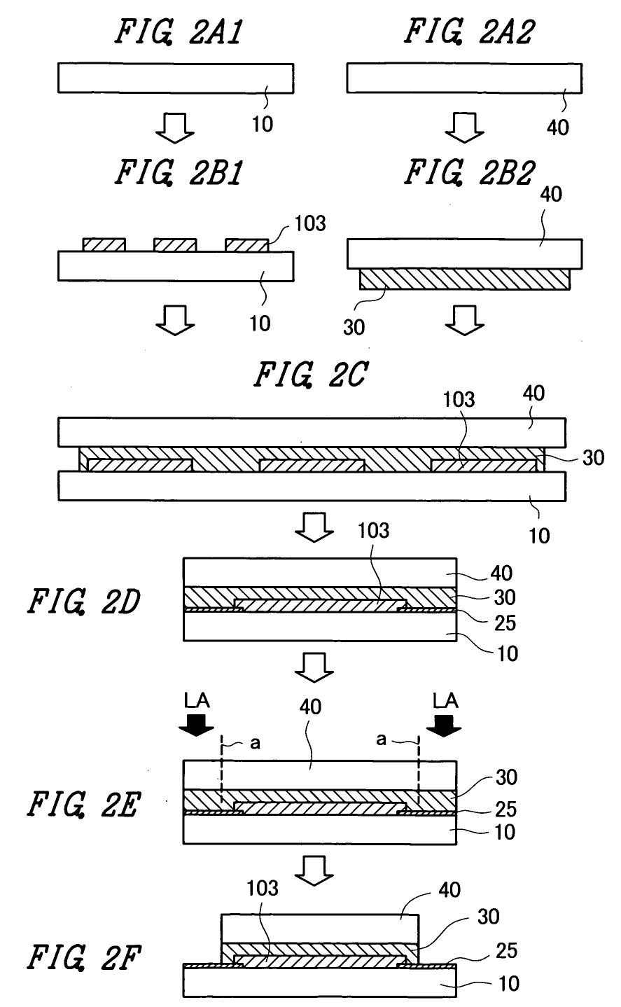

FIGS. 2A1-2F are views showing manufacturing steps of the organic EL display device of the present invention. FIG. 2(Al) shows a mother element substrate 10 made of glass. From this mother element substrate 10, a plurality of organic EL display panels for constituting a plurality of the organic EL display devices are formed. A plate thickness of the element substrate 10 is set to 0.5 mm, for example. FIG. 2(B1) shows a state that organic EL elements 103 are formed on the element substrate 10. In this specification, the organic EL element 103 is a general term used to collectively indicate a display region which includes organic EL layers 22 formed in a matrix array, TFTs, power source lines, video signal lines or the like for driving the organic EL layers 22. The element substrate 10 shown in FIG. 2(B1) is a mother element substrate 10 on which a plurality of organic EL elements 103 are formed. The mother element substrate 10 is adhered to the mother sealing substrate 40 and, thereafter, is separated into the plurality of organic EL display panels.

FIG. 2(A2) shows the mother sealing substrate 40 for protecting the organic EL layer 22. The mother sealing substrate 40 also has the substantially same size as the element substrate 10 shown in FIG. 2(Al). The mother sealing substrate 40 is separated later into a plurality of sealing substrates 40 which constitutes the organic EL display panels. FIG. 2(B2) shows a state that one large-sized resin sheet 30 is laminated to the mother sealing substrate 40. The resin sheet 30 is made of an acrylic resin. In this lamination step, in a reduced pressure atmosphere, the resin sheet 30 is heated to a temperature which falls within a range between 50° C. and 120° C. and pressure is applied to the resin sheet 30.

In FIG. 2(B2), the resin sheet 30 is not yet separated and only one resin sheet 30 is laminated to the mother sealing substrate 40 and hence, the lamination operation can be easily performed. The accurate alignment between the resin sheet 30 and the mother sealing substrate 40 is also unnecessary. Further, it is unnecessary to apply forming to the resin sheet 30 at this point of time and hence, there is no possibility of the occurrence of problems such as contamination of the resin sheet 30.

FIG. 2(C) is a view showing a state in which the element substrate 10 on which a plurality of organic EL elements 103 is formed and the sealing substrate 40 which includes the resin sheet 30 are laminated to each other. The adhesion between the element substrate 10 and the sealing substrate 40 is performed by laminating the resin sheet 30 to the element substrate 10. Lamination of the resin sheet 30 to the element substrate 10 is performed such that, in a reduced pressure atmosphere, the sealing substrate 40 is pressed to the element substrate 10 in a state that the element substrate 10 is heated to a temperature which falls within a range between 50C and 120° C.

In the steps shown, it is preferable to perform steps ranging from step shown in FIG. 2(B2) to step shown in FIG. 2(C) in a nitrogen atmosphere in which a dew point temperature is −50° C. or below and, more preferably −70° C. or below, and the oxygen concentration is 100 ppm, more preferably 1 ppm or less. Such conditions are particularly important when the resin sheet 30 is made of a material having water absorbing property.

In FIG. 2(C), only one resin sheet 30 is adhered to the mother sealing substrate 40. Accordingly, the accurate alignment between the mother element substrate 10 and the mother sealing substrate 40 is unnecessary in laminating the mother element substrate 10 and the mother sealing substrate 40 to each other. This implies that a manufacturing facility cost can be reduced and lowering of a yield rate in the sealing step can be reduced.

FIG. 2(D) shows a state in which the organic EL display panel formed in step shown in FIG. 2(C) is separated into the individual organic EL display panels. To separate the organic EL display panels from each other, the glass may be cut using laser beams, may be cut mechanically by dicing, or may be broken by scribing. In FIG. 2(D), the element substrate 10, the sealing substrate 40 and the resin sheet 30 which are obtained by cutting have the same size.

FIG. 2(E) shows a step in which the sealing substrate 40 and the resin sheet 30 are removed from the terminal portions 25 or the like of the separated organic EL display panel. In this embodiment, laser beams LA are radiated to an interface between the resin substrate 30 and the element substrate 10. Impact waves are generated in the element substrate 10 by radiating the laser beams and the resin sheet 30 is peeled off from the element substrate 10 by the impact waves. The laser beam radiation conditions of the laser beams LA at this point of time are set as explained previously.

Then, edge portions of the sealing substrate 40 are removed along dotted lines “a” in FIG. 2(E). The sealing substrate 40 can be most easily removed by scribing an upper portion of the sealing substrate 40 and breaking the sealing substrate 40 thereafter. Since the resin sheet 30 is adhered to the sealing substrate 40 at this point of time, when the sealing substrate 40 is removed, the resin sheet 30 is also removed simultaneously. With respect to a scribing method, flaws may be formed on a surface of the glass substrate by a cutter or cracks may be formed in only a surface of the sealing substrate 40 by radiating laser beams having a wavelength different from a wavelength of the laser beams for peeling off the resin sheet 30. Further, the edge portions of the sealing substrate 4 may be cut off by dicing. Also in this case, the edge portions of the resin sheet 30 are removed together with the edge portions of the sealing substrate 40.

FIG. 2(F) shows a state in which the terminal portions 25 formed on the edge portions of the element substrate 10 are exposed by removing the edge portions of the sealing substrate 40 and the edge portions of the resin sheet 30 in the above-mentioned manner. That is, FIG. 2(F) shows that the terminal portions 25 formed on the edge portions of the element substrate 10 are not covered with the resin sheet 30 and the sealing substrate 40.

In this embodiment, laser beams are radiated after separating the organic EL display panel into the individual organic EL display panels and hence, the present invention can acquire an advantageous effect that it is unnecessary to radiate laser beams to defective organic EL display panels. Further, laser beams are radiated to individual organic EL display panels and hence, the present invention can acquire an advantageous effect that the peeled-off resin sheet 30 can be removed each time the laser beam radiation is finished.

### EMBODIMENT 2

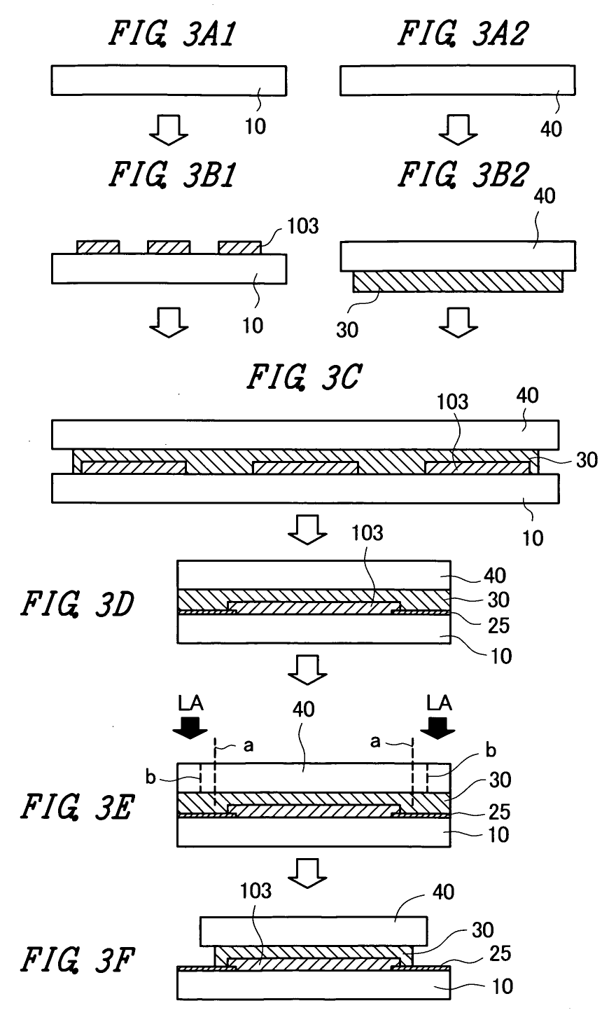

FIGS. 3A1-3F show another manufacturing method of the organic EL display device according to the present invention. Among the drawings, steps ranging from the step shown in FIG. 3(A) to the step shown in FIG. 3(D) are substantially equal to the corresponding steps of the embodiment 1. In FIG. 3(E), in the same manner as the embodiment 1, the resin sheet 30 is peeled off from the element substrate 10 by radiating laser beams LA to an interface between the resin sheet 30 and the element substrate 10 within ranges extending to positions indicated by dotted lines “a”. Radiation conditions of laser beams LA at this point of time are substantially equal to the corresponding conditions explained in conjunction with the embodiment 1 or the like. Radiation of the laser beams is performed in the ranges from edge portions of the sealing substrate 40 to the positions indicated by the dotted lines “a” and hence, portions of the resin sheet which falls within this range are peeled off from the element substrate 10.

As shown in FIG. 3(E), after the radiation of the laser beams, the edge portions of the sealing substrate 40 are removed at the positions indicated by dotted lines “b”. Since the resin sheet 30 and the sealing substrate 40 are adhered to each other, when the edge portions of the sealing substrate 40 are removed, the resin sheet 30 is also removed simultaneously. At this point of time, portions of the resin sheet 30 to which the laser beams are radiated are peeled off from the element substrate 10 and hence, outside portions including the portions of the resin sheet 30 peeled off from the element substrate 10 are removed. That is, the edge portions of the resin sheet 30 are positioned more inside than the edge portions of the sealing substrate 40 and the edge portions of the element substrate 10. Accordingly, the edge portions of the resin sheet 30 are protected and hence, it is possible to surely prevent the peeling-off or the like of the resin sheet 30 from the edge portion thereof.

A method of removing the edge portions of the sealing substrate 40 is substantially equal to the method explained in conjunction with the embodiment 1. The sealing substrate 40 can be most easily removed by scribing an upper portion of the sealing substrate 40 and breaking the sealing substrate 40. With respect to a scribing method, flaws may be formed on a surface of the glass substrate by a cutter or cracks may be formed in only a surface of the sealing substrate 40 by radiating laser beams having a wavelength different from a wavelength of the laser beams for peeling off the resin sheet 30. Further, the edge portions of the sealing substrate 40 may be cut off by dicing. Also in this case, the edge portions of the resin sheet 30 are removed together with the edge portions of the sealing substrate 40.

FIG. 3(F) shows a state in which the edge portions of the sealing substrate 40 and the edge portions of the resin sheet 30 are removed. The state shown in FIG. 3(F) is substantially equal to the state shown in FIG. 2(F) except for that the edge portions of the resin sheet 30 are positioned more inside than the edge portions of the sealing substrate 40 and the edge portions of the element substrate 10.

### EMBODIMENT 3

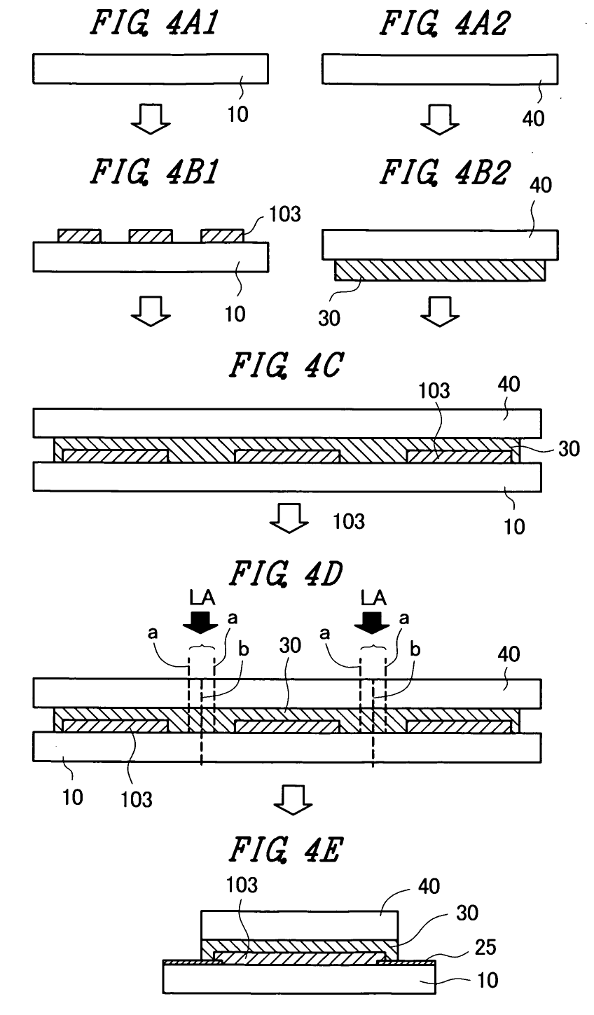

FIGS. 4A1-4E show another manufacturing method of the organic EL display device according to the present invention. Among those drawings, steps ranging from the step shown in FIG. 4(A) to the step shown in FIG. 4(C) are substantially equal to the corresponding steps of the embodiment 1. In FIG. 4(D), before separating the element substrate 10 or the sealing substrate 40 from each other, laser beams LA are radiated to an interface between the element substrate 10 and the resin sheet 30 within a range defined between dotted lines “a” which are positioned between the organic EL elements so as to peel off the resin sheet 30. In the same manner as the embodiment 1, the laser beams LA are radiated by focusing on the interface between the element substrate 10 and the resin sheet 30. Radiation conditions of laser beams LA are substantially equal to the corresponding conditions explained in conjunction with the embodiment 1 or the like.

Thereafter, the organic display panel is separated into individual organic EL display panels at positions indicated by dotted lines “b” in FIG. 4(D). The organic display panel may be cut by dicing or may be cut by fusing laser beams. Alternatively, the organic display panel may be broken by scribing the sealing substrate 40 or the element substrate 10 at positions indicated by the dotted lines “b”.

Thereafter, by scribing the sealing substrate 40 at the positions indicated by the dotted line “b” which falls within the same range as the element substrate 10 where the laser beams are radiated, edge portions of the sealing substrate 40 are removed. At this point of time, since the sealing substrate 40 and the resin sheet 30 are adhered to each other, when the edge portions of the sealing substrate 40 are removed, portions of the resin sheet 30 are also removed simultaneously. Here, scribing may be performed at positions indicated by the dotted lines “b” before the organic EL display panel is separated into the individual organic EL display panels.

A point which makes this embodiment different from the embodiment 1 is as follows. In the embodiment 1, the resin sheet 30 is peeled off from the element substrate 10 by radiating the laser beams after separating the mother substrate into the individual the organic EL display panels. On the other hand, in this embodiment, portions of the resin sheet 30 are peeled off from the mother element substrate 10 by radiating the laser beams before the mother substrate is separated into the individual organic EL display panels. The advantageous effect of this embodiment lies in that the number of times of the laser beam radiation can be halved compared to the number of times of laser beam radiation of the embodiment 1 and hence, a throughput can be enhanced.

### EMBODIMENT 4

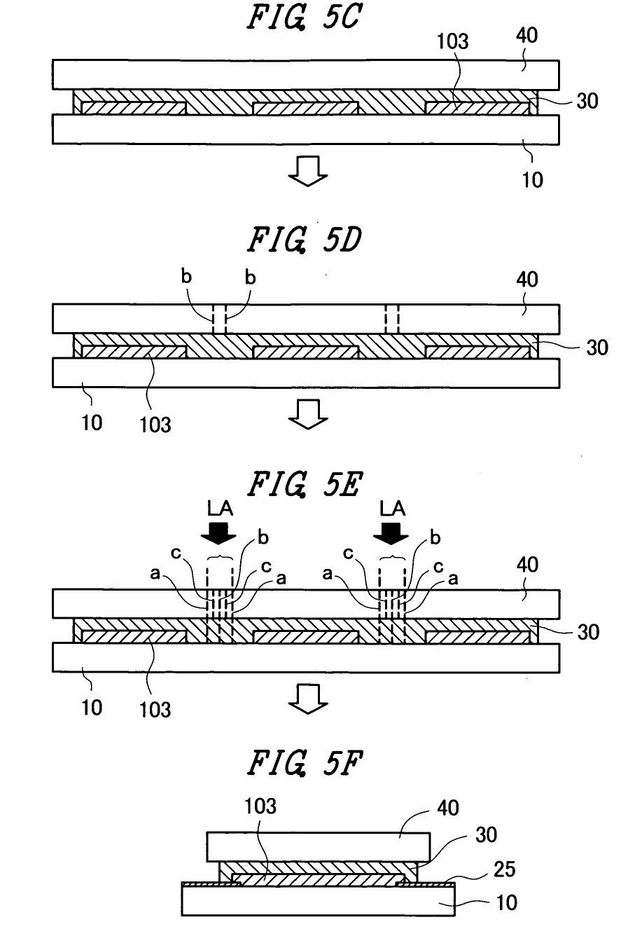

FIGS. 5A-5D show another manufacturing method of the organic EL display device according to the present invention. In the drawings, steps which are performed before the step shown in FIG. 5(A) are substantially equal to the corresponding steps of the embodiment. As shown in FIG. 5(B), the mother sealing substrate 40 is scribed at positions indicated by dotted lines “c” in advance. The dotted lines “c” indicate positions which become edge portions of the sealing substrate 40 after the mother substrate is separated into the individual organic EL display panels. The mother substrate may be scribed using a cutter, or the mother substrate may be scribed by forming cracks in glass by radiating laser beams having a wavelength different from a wavelength of the laser beams thus peeling off the resin sheet 30.

Thereafter, as shown in FIG. 5(C), by radiating the laser beams LA to an interface between the element substrate 10 and the resin sheet 30 within a range defined between the dotted lines “a”, the resin sheet 30 is peeled off from the element substrate 10. In the same manner as the embodiment 1, the laser beams are radiated by focusing on the interface between the element substrate 10 and the resin sheet 30. Further, radiation conditions of laser beams are substantially equal to the corresponding radiation conditions explained in conjunction with the embodiment 1 or the like. Thereafter, the mother sealing substrate 40 and the mother element substrate 10 are cut along the dotted lines “b” shown in FIG. 5(C) thus separating the mother substrate into the individual organic EL display panels.

Further, by applying an impact to portions of the sealing substrate 40 where scribing is previously made along dotted lines “c”, edge portions of the sealing substrate 40 are removed. At this point of time, the edge portions of the sealing substrate 40 to be removed and the resin sheet 30 are adhered to each other, the edge portions of the resin sheet 30 which are peeled off are simultaneously removed together with the edge portions of the sealing substrate 40.

In this embodiment, the edge portions of the resin sheet 30 retract more inwardly than the edge portions of the sealing substrate 40 and the edge portions of the element substrate 10 and hence, the resin sheet 30 is mechanically protected. Accordingly, it is possible to prevent the deterioration or the like of sealing effect which is caused by peeling-off of the resin sheet 30 or the like. This embodiment can halve the number of times of laser beam radiation compared to the number of times of laser beam radiation of the embodiment 2 and hence, a throughput can be enhanced correspondingly.

### EMBODIMENT 5

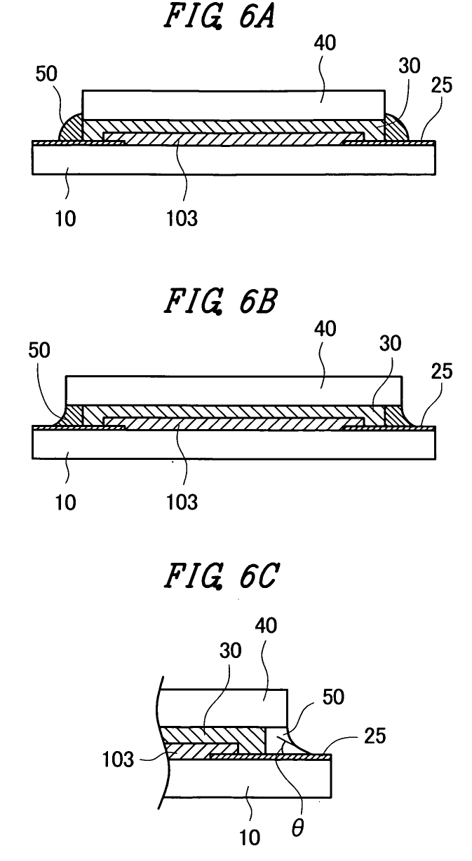

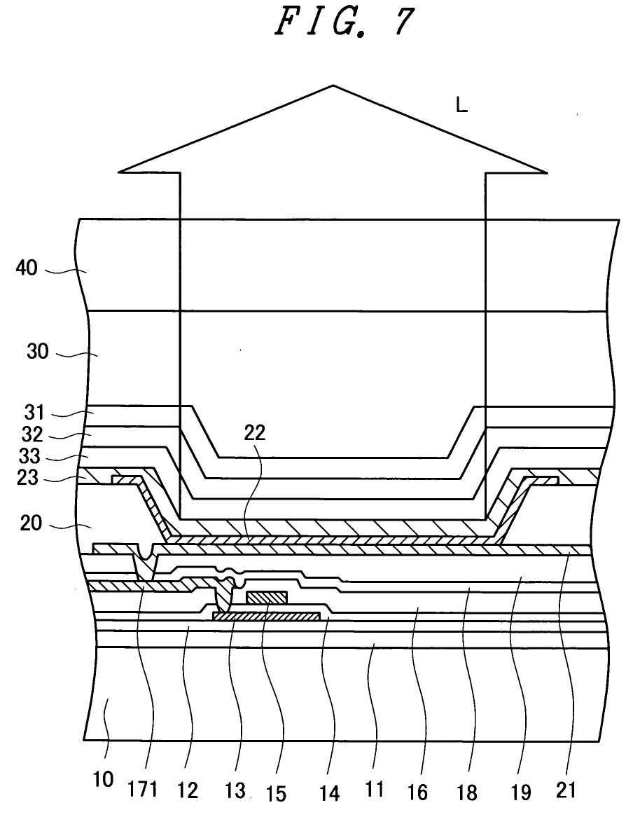

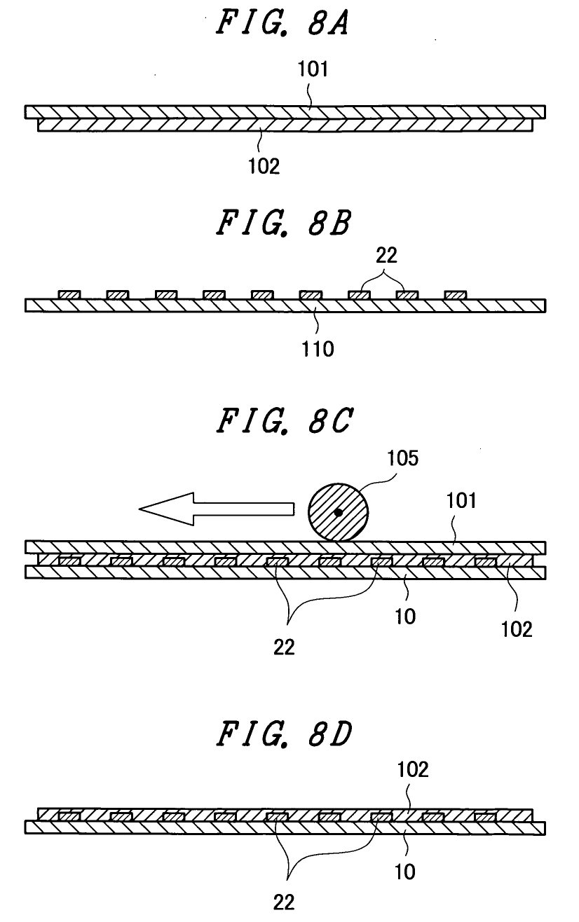

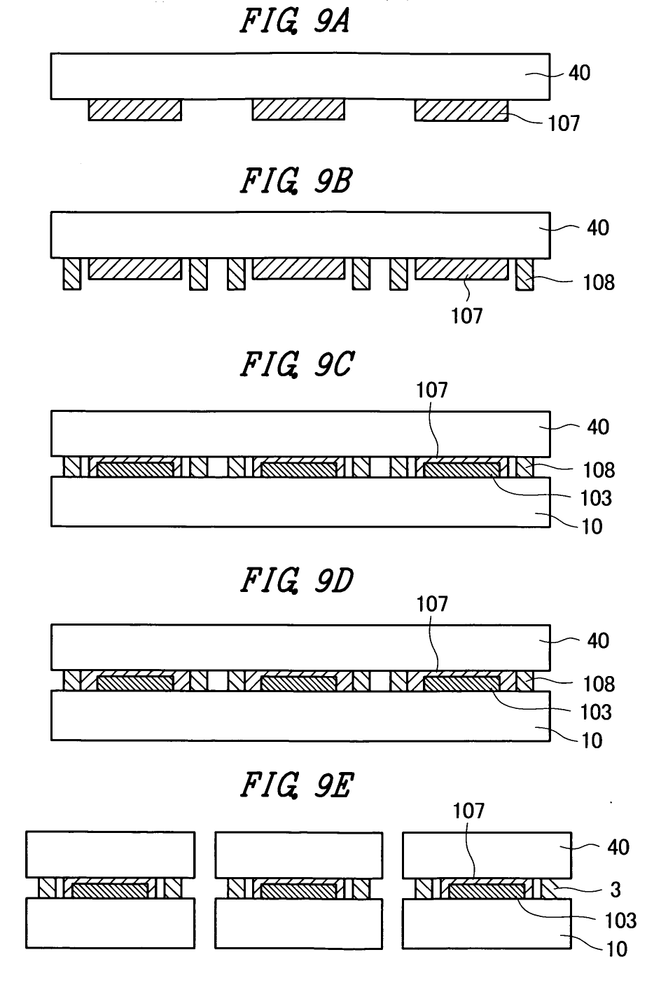

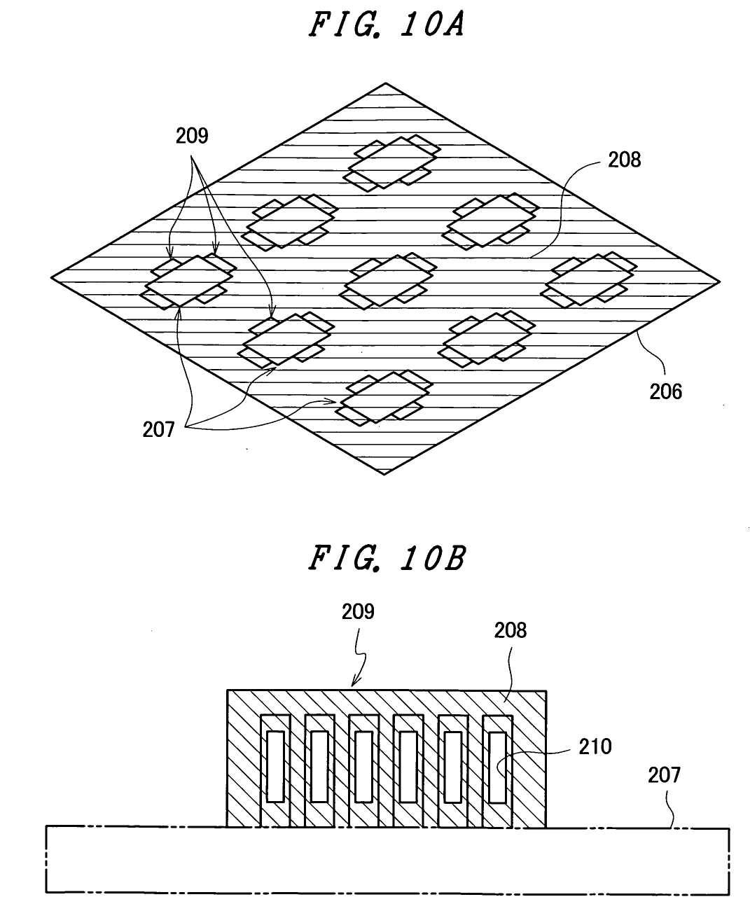

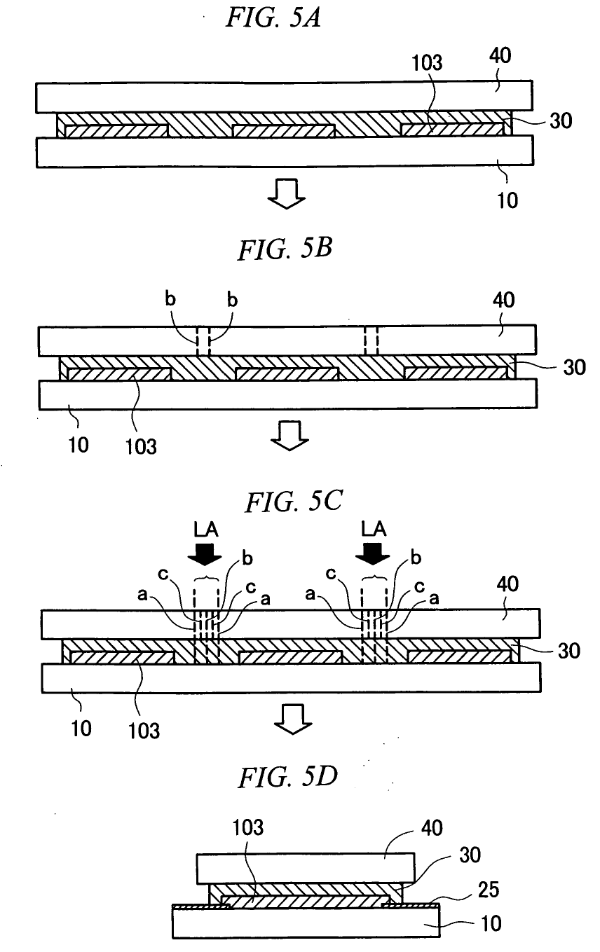

FIG. 6A to FIG. 6C are schematic cross-sectional views showing an organic EL display device of an embodiment 5. In FIG. 6A, an organic seal 50 is formed on edge portions of the sealing substrate 40 and the resin seat 30 of the organic EL display panel which are manufactured in accordance with the embodiment 1 or the embodiment 3. The organic seal 50 is formed for preventing the intrusion of moisture into the organic EL display panel from the edge portions of the sealing substrate 40 and the resin seat 30.

That is, the resin sheet 30 and the element substrate 10 on which the organic EL layers 22 are formed are laminated to each other and are adhered to each other usually. However, depending on conditions, there exists possibility that moisture intrudes into an interface between the element substrate 10 and the resin sheet 30. This embodiment is provided for preventing such intrusion of moisture.

In FIG. 6A, the organic seal 50 may be formed using a silicon resin, an acrylic resin or the like. The organic seal 50 may be applied to an edge portion of the sealing substrate 40 and an edge portion of the resin sheet 30 using a dispenser by coating. Viscosity of the organic seal 50 to be applied by coating may be set to a value suitable for coating using the dispenser.

The constitution shown in FIG. 6B is provided for more surely protecting the organic EL layer 22 from moisture by forming the organic seal 50 on the edge portion of the resin sheet 30 in the organic EL display panel manufactured in the embodiment 2 or in the embodiment 4. In the organic EL display device manufactured in the embodiment 2 or in the embodiment 4, the edge portion of the resin sheet 30 is retracted more inside than the element substrate 10 or the sealing substrate 40.

Due to such constitution, the organic seal 50 may be formed using a material which exhibits low viscosity and the organic seal 50 may be impregnated between the sealing substrate 40 and the element substrate 10. The organic seal 50 is formed using an acrylic resin having viscosity of approximately 70 Poise to 200 Poise. With the use of acrylic resin having such viscosity, the organic seal 50 can be formed using a so-called underfill method.

The organic seal 50 which is formed using such a method exhibits low viscosity and hence, as shown in FIG. 6C, a contact angle θ can be set to a value smaller than 90°. FIG. 6C is an enlarged view of FIG. 6B. By setting the contact angle θ to the value smaller than 90°, it is possible to improve the adhesion between the organic seal 50 and the element substrate 10 or the sealing substrate 40. Further, a sealing length of the organic seal 50 to the organic EL layer 22 can be elongated and hence, it is possible to more surely protect the organic EL layers 22 from moisture.

### EMBODIMENT 6

FIG. 7 is a cross-sectional view of a display part of an organic EL display device according to the embodiment 6 of the present invention. As shown in FIG. 7, the constitution of this embodiment 6 ranging from an element substrate 10 to an upper electrode 23 is substantially equal to the corresponding constitution of the embodiment 1 shown in FIG. 1. The technical feature of the constitution of this embodiment shown in FIG. 7 lies in that a three-layered inorganic protective film consisting of a first protective film 31, a second protective film 32 and a third protective film 33 is formed on the upper electrode 23 for protection against moisture. Due to the provision of the inorganic protective film, in laminating a resin sheet 30 to an element substrate 10 by way of the inorganic protective film, when moisture intrudes into an interface between a resin sheet 30 and the upper electrode 23 of an organic EL layer 22, it is possible to block the moisture.

In FIG. 7, the first protective film 31 is formed of an SiNx film, an SiOx film or an SiNxOy film, for example, the second protective film 32 is formed of an MgO film, for example, and the third protective film 33 is formed of an SiNx film, an SiOx film or an SiNxOy film, for example. The third protective film 33 blocks moisture which intrudes between the resin sheet 30 and the upper electrode 23. The second protective film 32 is made of MgO which possesses moisture absorbing property. The MgO film absorbs moisture which intrudes through pin holes or the like formed in the first protective film 31 thus playing a role of preventing the intrusion of moisture to the organic EL layers 22 side. The third protective film 33 blocks moisture which cannot be absorbed by the second protective film 32 and passes the second protective film 32.

The resin sheet 30 is laminated to the first protective film 31. Before being laminated to the first protective film 31, the resin sheet 30 is laminated to the sealing substrate 40. The resin sheet 30 which is in a form of a large sheet is firstly laminated to the mother sealing substrate 40 and, thereafter, the resin sheet 30 is laminated to the element substrate 10. With respect to a manufacturing method of the organic EL display device which is performed thereafter, any one of manufacturing methods explained in conjunction with the embodiment 1 to the embodiment 5 can be used.

In this embodiment, the explanation has been made with respect to the case in which the three-layered protective film is used. However, the protective film is not limited to such a three-layered protective film and may be a one-layered film or a two-layered film. When the protective film is formed of the one-layered film or the two-layered film, it is preferable to use a SiNx film, a SiOx film or a SiNxOy film. However, it is preferable to adopt the three-layered structure because MgO possesses moisture absorbing property and hence, by using MgO in a form that MgO is sandwiched between the SiNx film, the SiOx film, the SiNxOy film or the like, it is possible to acquire more effective moisture prevention.

As described above, according to this embodiment, by forming the protective film between the upper electrode 23 of the organic EL layers 22 and the resin sheet 30, it is possible to more surely perform the protection of the organic EL layers 22 against moisture compared to cases described in the embodiments to 5.

In the above-mentioned embodiments, the explanation has been made with respect to the case in which the organic EL display device is the top-emission-type organic EL display device. However, it is needless to say that the present invention is also applicable to a case in which the organic EL display device is a bottom-emission-type organic EL display device.

What is claimed is:

1. An organic EL display device comprising:
an element substrate which includes a display region on which pixels each of which has an upper electrode, a lower electrode, and an organic EL layer sandwiched between the upper electrode and the lower electrode are formed in a matrix array and a terminal portion which supplies an electric current and a signal to the display region; and
a sealing substrate which seals the display region, wherein
a resin sheet is sandwiched between the element substrate and the sealing substrate, and the resin sheet is removed from the terminal portion by impact peeling using laser beams.

2. An organic EL display device according to claim 1, wherein the resin sheet is laminated to the sealing substrate, and the resin sheet is also laminated to the element substrate.

3. An organic EL display device according to claim 1, wherein an edge portion of the resin sheet retracts more inwardly than an edge portion of the sealing substrate and an edge portion of the element substrate.

4. An organic EL display device according to claim 1, wherein an organic seal is formed on an edge portion of the resin sheet.

5. An organic EL display device according to claim 1, wherein a protective film is formed on the upper electrode.

6. An organic EL display device according to claim 5, wherein the protective film is an inorganic film and contains any one of SiNx, SiOx and SiNxOy.

7. A manufacturing method of an organic EL display device which includes an element substrate which includes a display region on which pixels each of which has an upper electrode, a lower electrode, and an organic EL layer sandwiched between the upper electrode and the lower electrode are formed in a matrix array and a terminal portion which supplies an electric current and a signal to the display region; a sealing substrate which seals the display region; and a resin sheet which is sandwiched between the element substrate and the sealing substrate, the manufacturing method comprising the steps of:
manufacturing a mother element substrate on which a plurality of element regions each of which has the display region and the terminal portion are formed;
laminating one resin sheet to a mother sealing substrate;
laminating the mother element substrate and the mother sealing substrate to each other by way of the resin sheet thus manufacturing a mother organic EL display panel;
separating the mother organic EL display panel into a plurality of individual organic EL display panels; and
radiating laser beams to a terminal portion of the separated organic EL display panel thus peeling off the resin sheet from the terminal portion by impact waves generated by the laser beams.

8. A manufacturing method of an organic EL display device which includes an element substrate which includes a display region on which pixels each of which has an upper electrode, a lower electrode, and an organic EL layer sandwiched between the upper electrode and the lower electrode are formed in a matrix array and a terminal portion which supplies an electric current and a signal to the display region; a sealing substrate which seals the display region, and a resin sheet which is sandwiched between the element substrate and the sealing substrate, the manufacturing method comprising the steps of:
manufacturing a mother element substrate on which a plurality of element regions each of which has the display region and the terminal portion are formed;
laminating one resin sheet to the mother sealing substrate;
laminating the mother element substrate and the mother sealing substrate to each other by way of the resin sheet thus manufacturing a mother organic EL display panel;
radiating laser beams to the terminal portion of the element region thus peeling off the resin sheet from the terminal portion by impact waves generated by the laser beams; and
separating the mother organic EL display panel for respective element regions.
